(19) United States
(12) Patent Application Publication
(10) Pub. No.: US 2008/0011799 A1
(43) Pub. Date: Jan. 17, 2008

(54) Solar energy backpack combination device

(76) Inventor: I-Chun Chang, Taoyuan City (TW)

Correspondence Address: TROXELL LAW OFFICE PLLC, SUITE 1404, 5205 LEESBURG PIKE, FALLS CHURCH, VA, 22041, US

(21) Appl. No.: 11/713,100

(22) Filed: Mar. 2, 2007

(30) Foreign Application Priority Data
Apr. 21, 2006 (TW) 095206852

(51) Int. Cl. A45F 3/00; H01L 31/042

(52) U.S. Cl. 224/576

(57) ABSTRACT

A solar energy backpack combination device, in which a solar energy backpack is provided with a plurality of item carrying pockets each configured with an electric power unit. Joining devices are used to install the electric power units into the plurality of item carrying pockets of the solar energy backpack to face the light. The electric power units are each configured with a solar panel facing the light, and the solar panel is electrically connected to an electric storage device configured with a battery charging slot and a storage battery, and the storage battery is electrically connected to a plurality of connecting terminals. Accordingly, light rays are converted into electrical energy and stored in the electric storage devices, whereafter an electric power consuming device can be connected to the solar energy backpack to obtain the needed electric power from the storage battery of the electric storage device.

### BACKGROUND OF THE INVENTION

(a) Field of the Invention

The present invention provides a solar energy backpack combination device, in which a solar energy backpack enables light rays to be converted into electrical energy, and after electric storage devices store the electrical energy, a power consuming device can be connected to connecting terminals of the solar energy backpack.

(b) Description of the Prior Art

The only function of a conventional backpack is to hold items, such as when climbing a mountain, all climbers carry with them emergency equipment that consume power, such as a flashlight, a camera, an electric heater device, a handheld communication device, and so on. However, a large quantity of batteries must be prepared before climbing a mountain in case battery power of the emergency equipment is exhausted while climbing and battery charging cannot be carried out. Hence, only by carrying a large quantity of batteries can the power dependent equipment be used for long periods of time. Such a situation results in the climber having to bear the heavy weight of the batteries, and replacing batteries does not conform to the concept of environmental protection.

Hence, the inventor of the present invention proposes to resolve and surmount existent technical difficulties to eliminate the aforementioned shortcomings of prior art.

### SUMMARY OF THE INVENTION

The present invention provides a solar energy backpack combination device which includes a solar energy backpack that enables light rays to be converted into electrical energy, and after electric storage devices store the electrical energy, a power consuming device can be connected to connecting terminals of the solar energy backpack, thereby enabling the power consuming device to obtain required electric power through storage batteries of the electric storage devices.

To enable a further understanding of said objectives and the technological methods of the invention herein, brief description of the drawings is provided below followed by detailed description of the preferred embodiments.

### BRIEF DESCRIPTION OF THE DRAWINGS

FIG. 1 shows a schematic elevational view according to the present invention.

FIG. 2 shows an exploded schematic elevational view according to the present invention.

FIG. 3 shows a block diagram of a solar energy device according to the present invention.

FIG. 4 shows a first embodiment according to the present invention.

FIG. 5 shows a second embodiment according to the present invention.

FIG. 6 shows a third embodiment according to the present invention.

### DETAILED DESCRIPTION OF THE PREFERRED EMBODIMENTS

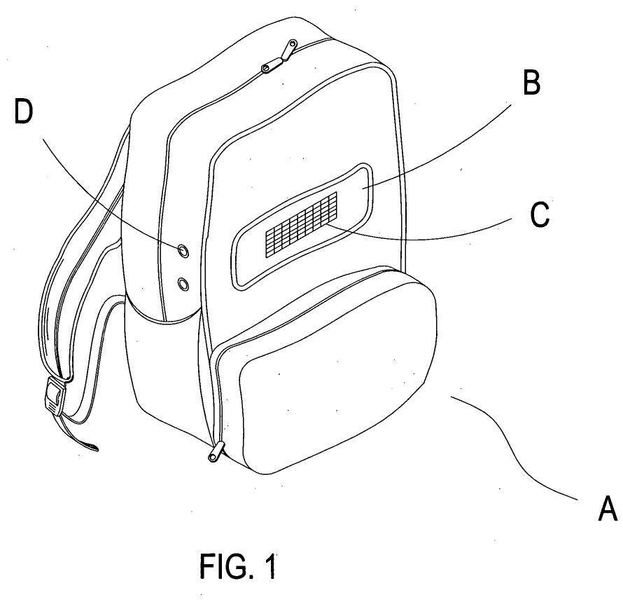

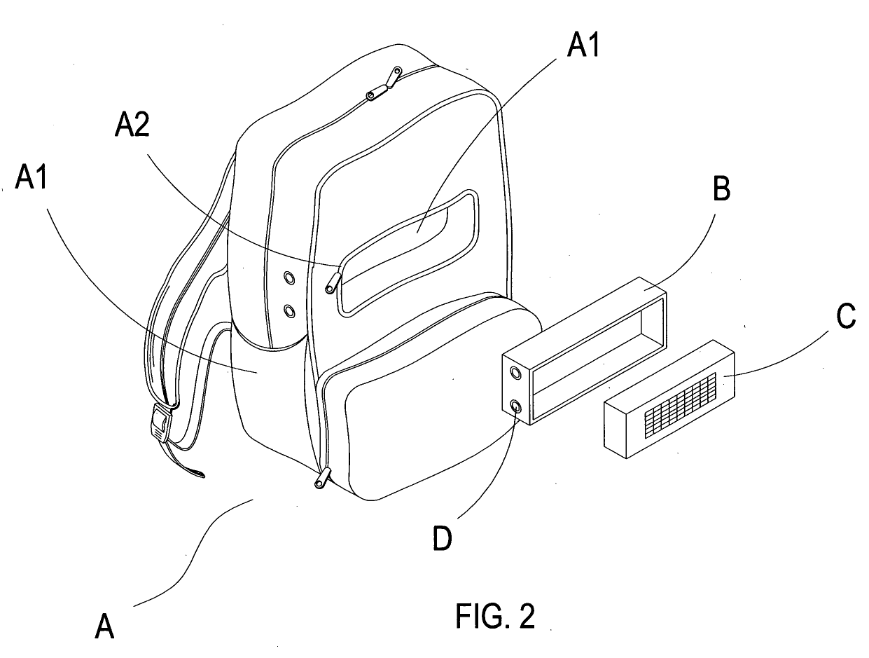

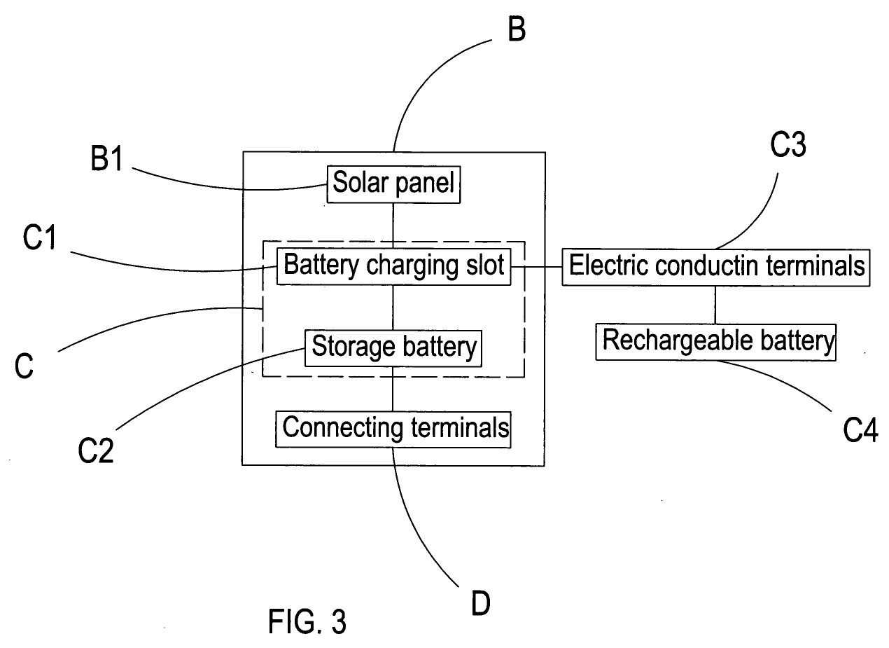

Referring to FIG. 1, FIG. 2 and FIG. 3, wherein a solar energy backpack A of a solar energy backpack combination device of the present invention is structured to comprise electric power units B, electric storage devices C and connecting terminals D.

The solar energy backpack A is configured with a plurality of item carrying pockets A1, interior of each of which is respectively disposed the electric power units B. Various types of joining devices A2 are used to enable disposing the electric power units B into the plurality of item carrying pockets A1 of the solar energy backpack A to face the light.

The electric power units B are each configured with a solar panel B1 facing the light, and the solar panel B1 is electrically connected to the electric storage device C. The electric storage device C is configured with a battery charging slot C1 and a storage battery C2, and the storage battery C2 is electrically connected to the plurality of connecting terminals D.

The battery charging slot C1 of the electric storage device C is configured with electric conducting terminals C3 that enable electrical connection to a rechargeable battery C4. The rechargeable battery C4 is able to serve as an independent power supply device to supply electric power required by the electric power unit B through the electric conducting terminals C3.

Accordingly, the present invention is characterized in that after converting light rays into electrical energy and storing the electrical energy in the electric storage devices C, a portable electric power consuming device can then be connected to the connecting terminals D of the solar energy backpack A, thereby enabling the portable electric power consuming device to obtain the needed electric power from the storage battery C2 of the electric storage device C.

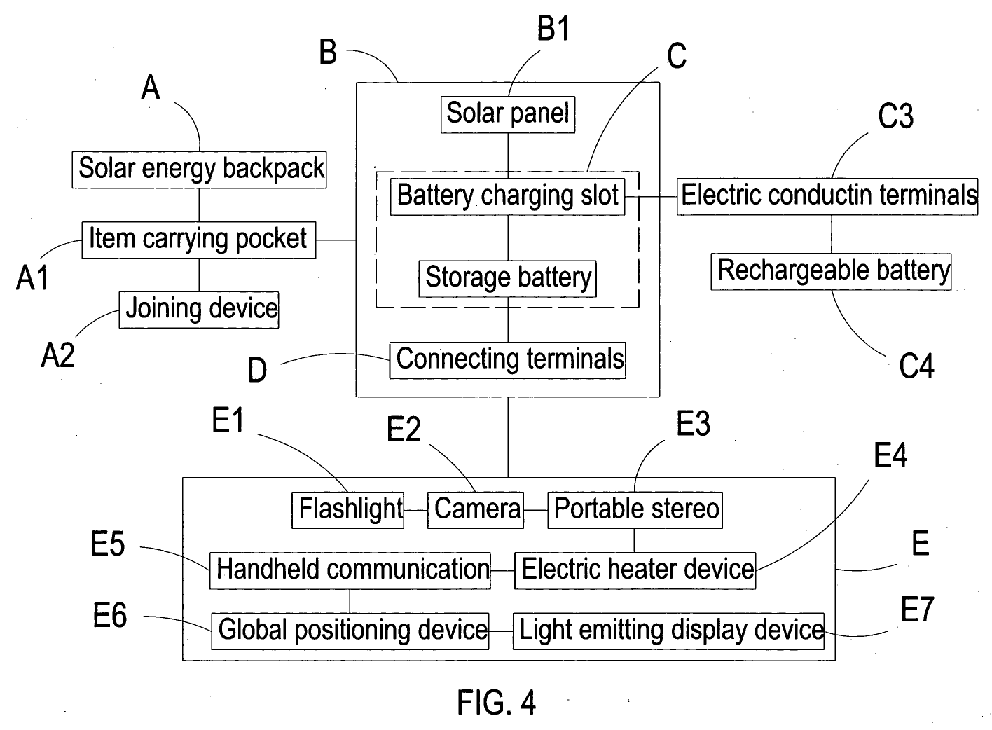

Referring to FIG. 4, wherein an embodiment of the solar energy backpack A of the solar energy backpack combination device of the present invention is provided with a plurality of the item carrying pockets A1, and the electric power units B are configured in the plurality of item carrying pockets A1. Various types of joining devices A2 are used to enable disposing the electric power units B into the plurality of item carrying pockets A1 of the solar energy backpack A to face the light.

When the solar panels B1 of the electric power units B are irradiated by light rays, then the electric storage devices C electrically connected to the solar panels B1 convert the light rays into electrical energy, which is then stored, thereby enabling the electric storage devices C to achieve the objective of supplying electrical power through use of the connecting terminals D. Moreover, the connecting terminals D enable the electric power consuming device E to be connected thereto, thereby facilitating supplying electric power required by the electric power consuming device E.

The battery charging slot C1 of the electric storage device C is configured with the electric conducting terminals C3 that enable electrical connection to the rechargeable battery C4. The rechargeable battery C4 is able to serve as an independent power supply device to supply electric power required by the electric power unit B through the electric conducting terminals C3.

The electric power consuming device E can be a flashlight E1, a camera E2, a portable stereo E3, an electric heater device E4, a handheld communication device E5, a global positioning device E6, a light emitting display device E7 and related portable electric power consuming devices. Moreover, the connecting terminals D can be configured as sound source terminals, signal terminals, power source terminals and related input/output terminals.

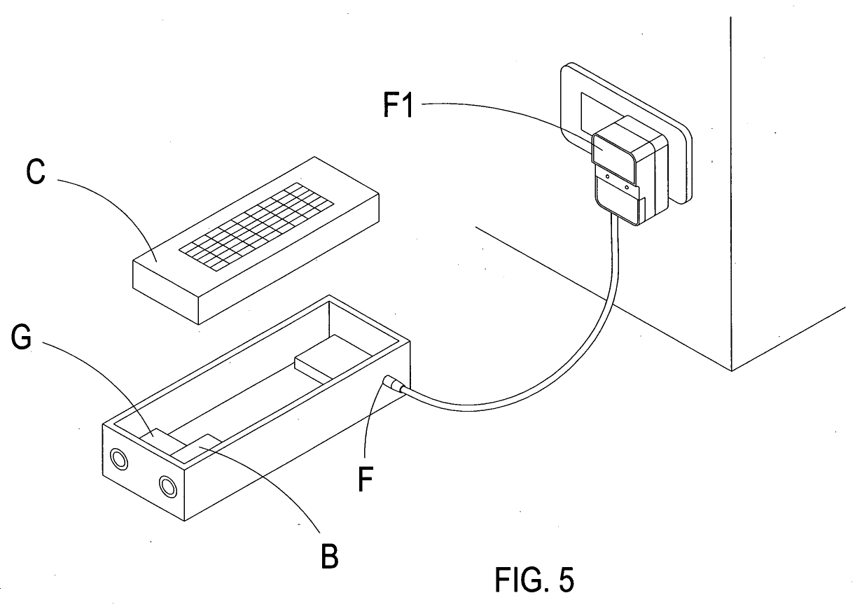

Referring to FIG. 5, which shows the electric storage device C comprising a power source terminal F that is correspondingly configured to a battery charger F1, wherein the battery charger F1 is connected to a mains power supply to enable recharging of the electric storage device C. Moreover, the electric power unit B further comprises a hand operated generator G, thereby enabling a user to recharge the electric storage device C by shaking the hand operated generator G.

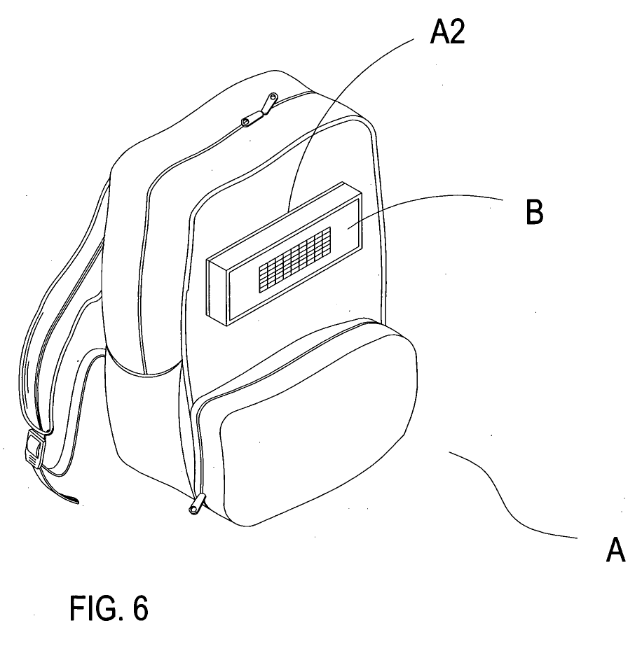

Referring to FIG. 6, which shows the electric power unit B further configured on areas of shoulder straps, a surface and related areas of the solar energy backpack A facing the light. The joining device A2 can be buttons, a zip fastener, a hook and loop fastener strip and related fastener devices. Furthermore, the solar energy backpack A can be a briefcase, a handbag, a mountain climbing backpack and related portable backpacks.

In order to better explicitly disclose advancement and practicability of the present invention, a comparison with prior art is described hereinafter:

Shortcomings of Prior Art

1. Only provides functionality to hold items.

2. A large quantity of batteries must be prepared in advance, resulting in having to bear the heavy weight of the batteries.

3. Having to replace batteries does not conform to the concept of environmental protection.

Advantages of the Present Invention

11. Apart from providing functionality to hold items, the present invention is also able to supply electric power required by electric power consuming devices.

2. Eliminates the need to prepare batteries in advance, thereby reducing weight of items needed to be carried.

3. The electric power units B are able to directly supply electric power, thereby reducing use of batteries and thus conforming to the concept of the environmental protection.

4. The solar panels B1 are used to implement battery charging.

5. Because of advantage 4, thus, the expense of having to replace batteries is reduced.

6. Provided with advancement and practicability.

7. Enhances industrial competitiveness.

In conclusion, the present invention in overcoming structural shortcomings of prior art has assuredly achieved effectiveness of anticipated advancement, and, moreover, is easily understood by persons unfamiliar with related art. Furthermore, contents of the present invention have not been publicly disclosed prior to this application, and practicability and advancement of the present invention clearly comply with essential elements as required for a new patent application. Accordingly, a new patent application is proposed herein.

It is of course to be understood that the embodiments described herein are merely illustrative of the principles of the invention and that a wide variety of modifications thereto may be effected by persons skilled in the art without departing from the spirit and scope of the invention as set forth in the following claims.

What is claimed is:

1. A solar energy backpack combination device, wherein a solar energy backpack is provided with a plurality of item carrying pockets each disposed with an electric power unit, various types of joining devices are used to dispose the electric power units to areas of the solar energy backpack facing the light, the electric power units of the plurality of item carrying pockets are each configured with a solar panel, each of which is electrically connected to an electric storage device, the electric storage device is configured with a battery charging slot and a storage battery, and the storage battery of the electric storage device is electrically connected to a plurality of connecting terminals;
whereby the solar panels are able to convert light rays into electrical energy, and the electric storage devices store the electrical energy, thereby enabling a power consuming device to be connected to the connecting terminals of the solar energy backpack, thus, the power consuming device is able to obtain required electric power through the storage batteries of the electric storage devices.

2. The solar energy backpack combination device according to claim 1, wherein the joining device can be buttons, a zip fastener, a hook and loop fastener strip and related fastener devices.

3. The solar energy backpack combination device according to claim 1, wherein the electric power units are configured on areas of shoulder straps, a surface and related areas of the solar energy backpack facing the light.

4. The solar energy backpack combination device according to claim 1, wherein the electric storage device comprises a power source terminal that is correspondingly configured to a battery charger, the battery charger is connected to a mains power supply, thereby enabling a user to directly recharge the electric storage device.

5. The solar energy backpack combination device according to claim 1, wherein the electric power unit comprises a hand operated generator, thereby enabling a user to directly recharge the electric storage device by shaking the hand operated generator and through pressing actions.

6. The solar energy backpack combination device according to claim 1, wherein the electric power consuming device is a flashlight, a camera, a portable stereo, an electric heater device, a handheld communication device, a global positioning device, a light emitting display device and related portable electric power consuming devices.

7. The solar energy backpack combination device according to claim 1, wherein the connecting terminals are configured as sound source terminals, signal terminals, power source terminals and related input or output terminals.

8. The solar energy backpack combination device according to claim 1, wherein the solar energy backpack is a briefcase, a handbag, a mountain climbing backpack and related portable backpacks.
